(19) United States
(12) Patent Application Publication
(10) Pub. No.: US 2020/0258998 A1
(43) Pub. Date: Aug. 13, 2020

(54) METHOD OF MANUFACTURING SEMICONDUCTOR DEVICE

(71) Applicant: FUJI ELECTRIC CO., LTD., Kawasaki (JP)

(72) Inventor: Naoko KODAMA, Matsumoto-city (JP)

(73) Assignee: FUJI ELECTRIC CO., LTD., Kawasaki-shi (JP)

(21) Appl. No.: 16/859,637

(22) Filed: Apr. 27, 2020

Related U.S. Application Data
(63) Continuation of application No. PCT/JP2019/015367, filed on Apr. 8, 2019.

(30) Foreign Application Priority Data
May 10, 2018 (JP) 2018-091777

(51) Int. Cl. H01L 29/66; H01L 27/07

(52) U.S. Cl. CPC H01L 29/66348; H01L 27/0761; H01L 29/6609

(57) ABSTRACT

A method of manufacturing a semiconductor device that includes a semiconductor element. The method includes the steps of providing a semiconductor substrate of a first conductivity type, forming an element structure of the semiconductor element, at a first main surface of the semiconductor substrate, forming a first protective film at a second main surface of the semiconductor substrate, implanting ions in the semiconductor substrate from the second main surface having the first protective film formed thereon, and removing the first protective film.

### CROSS REFERENCE TO RELATED APPLICATIONS

This is a continuation application of International Application PCT/JP2019/015367 filed on Apr. 8, 2019 which claims priority from a Japanese Patent Application No. 2018-091777 filed on May 10, 2018, the contents of which are incorporated herein by reference.

### BACKGROUND OF THE INVENTION

### 1. Field of the Invention

Embodiments of the invention relate to a method of manufacturing a semiconductor device.

### 2. Description of the Related Art

Power devices are being developed in which characteristics are enhanced and improved through impurity defects that become lifetime killers and that are introduced by high-acceleration energy ion implantation. For example, in a known reverse conducting insulated gate bipolar transistor (RC-IGBT) having a structure in which an insulated gate bipolar transistor (IGBT) and a free wheeling diode (FWD) connected in antiparallel to the IGBT are integrated on a single semiconductor chip, defects that become lifetime killers are formed in an n⁻-type drift region by an irradiation helium (He).

FIGS. 8 and 9 are cross-sectional views of structures of conventional RC-IGBTs. In the conventional RC-IGBT depicted in FIG. 8, defects 115 due to helium irradiation are formed near an interface between an n⁻-type drift region 101 and a p-type base region 102. The defects 115 are formed in not only a FWD region 122 but also in an IGBT region 121. The IGBT region 121 is a region where an IGBT is disposed while the FWD region 122 is a region where a FWD is disposed. Further, as depicted in FIG. 9, to facilitate reductions in loss and leak current in the IGBT region 121, a RC-IGBT has been proposed in which the defects 115 are formed only in the FWD region 122.

In fabricating (manufacturing) such a RC-IGBT, the defects 115 are formed by performing high-acceleration ion implantation of a deep range, for example, helium (He) irradiation. When the defects 115 are also introduced in the IGBT region 121 like that depicted in FIG. 8, formation is by introducing the defects 115 from an entire back surface (side having a p⁺-type collector region 113 and an n⁺-type cathode region 114) of a semiconductor wafer 110. As depicted in FIG. 9, when the defects 115 are introduced in only the FWD region 122, formation is as depicted in FIG. 10.

FIG. 10 is a cross-sectional view schematically depicting a state of an ion implantation process in which a metal mask is used as a mask. When a metal mask 131 is used as a shielding film in the ion implantation of an impurity, alignment of the semiconductor wafer 110 and the metal mask 131 is performed using an alignment mark (positioning mark) formed in advance in the semiconductor wafer 110 as a reference, and respective main surfaces facing one another are fixed to be in contact with one another by, for example, a clip or screw (not depicted). Subsequently, with the semiconductor wafer 110 and the metal mask 131 in a fixed state, as depicted in FIG. 10, an irradiation 132 of an impurity (for example, He ions) by a high acceleration energy from the side having the metal mask 131 is performed, whereby defects and the impurity of a predetermined ion species are introduced into only a predetermined region.

FIG. 11 is a top view of alignment marks in a method of manufacturing the conventional RC-IGBT. A resist 119 is applied to the entire back surface of the semiconductor wafer 110 and the resist 119 is left only around alignment marks 118 so that positions of the alignment marks 118 are clearly indicated.

Further, as a technique of suppressing irradiation of a semiconductor wafer in which contaminants are attached to the metal mask, disposal of an absorber between the metal mask and the semiconductor wafer is commonly known; the absorber adjusts the depth of the ion irradiation (for example, refer to Japanese Laid-Open Patent Publication No. 2017-157795).

### SUMMARY OF THE INVENTION

According to an embodiment of the invention, a method of manufacturing a semiconductor device that includes a semiconductor element, includes:

providing a semiconductor substrate of a first conductivity type; forming an element structure of the semiconductor element, at a first main surface of the semiconductor substrate; forming a first protective film at a second main surface of the semiconductor substrate; implanting ions in the semiconductor substrate from the second main surface having the first protective film formed thereon; and removing the first protective film.

In the embodiment, the method further includes forming a second protective film at the first main surface of the semiconductor substrate after forming the element structure but before implanting the ions in the semiconductor substrate.

In the embodiment, the first protective film and the second protective film are formed using a same material.

In the embodiment, the first protective film is so formed that an end portion of the semiconductor substrate is exposed from the first protective film.

In the embodiment, forming the second protective film includes forming an alignment mark in the second protective film.

In the embodiment, forming the first protective film includes forming an alignment mark in the first protective film.

In the embodiment, forming the element structure includes forming an alignment mark at the first main surface of the semiconductor substrate.

In the embodiment, the method further includes grinding the second main surface of the semiconductor substrate between forming the element structure and forming the first protective film.

In the embodiment, the method further includes providing a metal mask at the second main surface of the semiconductor substrate after forming the first protective film but before implanting ions in the semiconductor substrate.

In the embodiment, the method further includes forming a back-surface structure of the semiconductor element, at the second main surface of the semiconductor substrate after forming the element structure but before forming the first protective film.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a flowchart of an outline of processes of a portion of a method of manufacturing the semiconductor device according to an embodiment.

FIG. 2 is a cross-sectional view schematically depicting a state of the semiconductor device in the processes of a portion of the method of manufacturing the semiconductor device according to the embodiment.

FIG. 3 is a cross-sectional view schematically depicting a state of the semiconductor device in the processes of a portion of the method of manufacturing the semiconductor device according to the embodiment.

FIG. 4 is a cross-sectional view schematically depicting a state of the semiconductor device in the processes of a portion of the method of manufacturing the semiconductor device according to the embodiment.

FIG. 5 is a plan view of alignment marks in the method of manufacturing the semiconductor device according to the embodiment.

FIG. 6 is a perspective view depicting installation of a metal mask in the method of manufacturing the semiconductor device according to the embodiment.

FIG. 7 is a cross-sectional view of an end portion of a semiconductor wafer in the method of manufacturing the semiconductor device according to the embodiment.

FIG. 8 is a cross-sectional view of a structure of a conventional RC-IGBT.

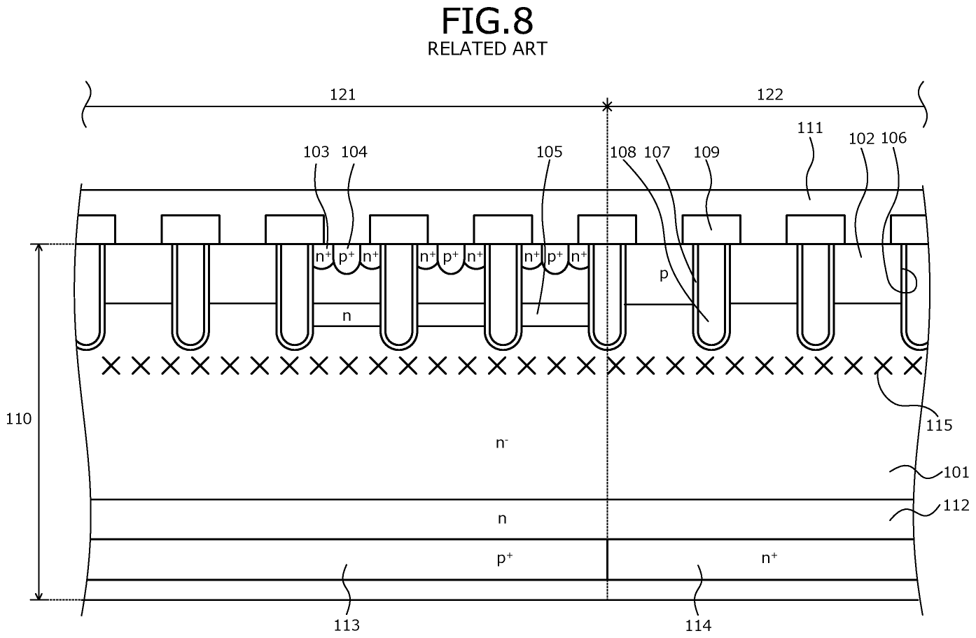

FIG. 9 is a cross-sectional view of a structure of a conventional RC-IGBT.

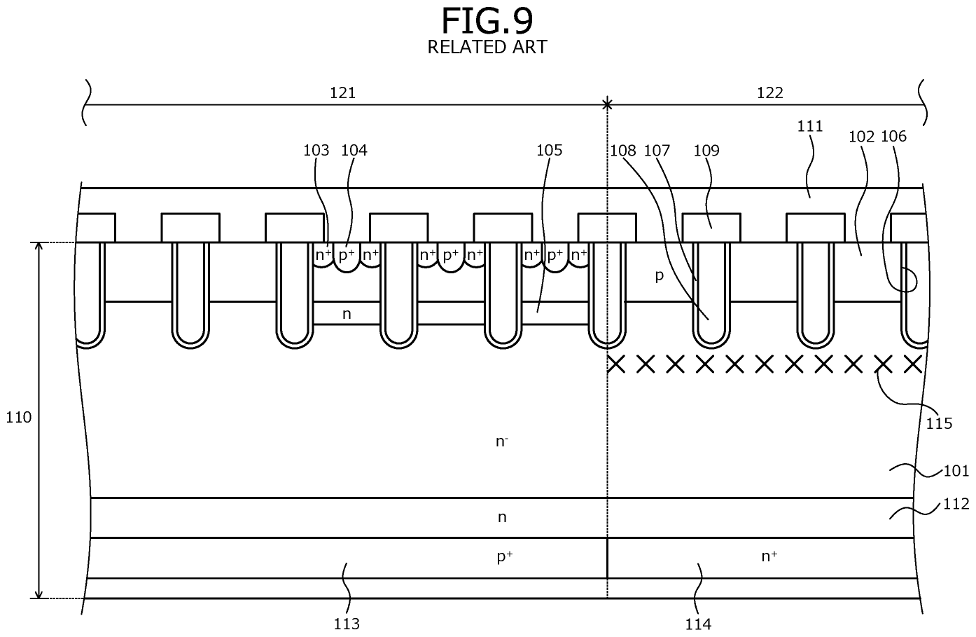

FIG. 10 is a cross-sectional view schematically depicting a state of an ion implantation process in which a metal mask is used as a mask.

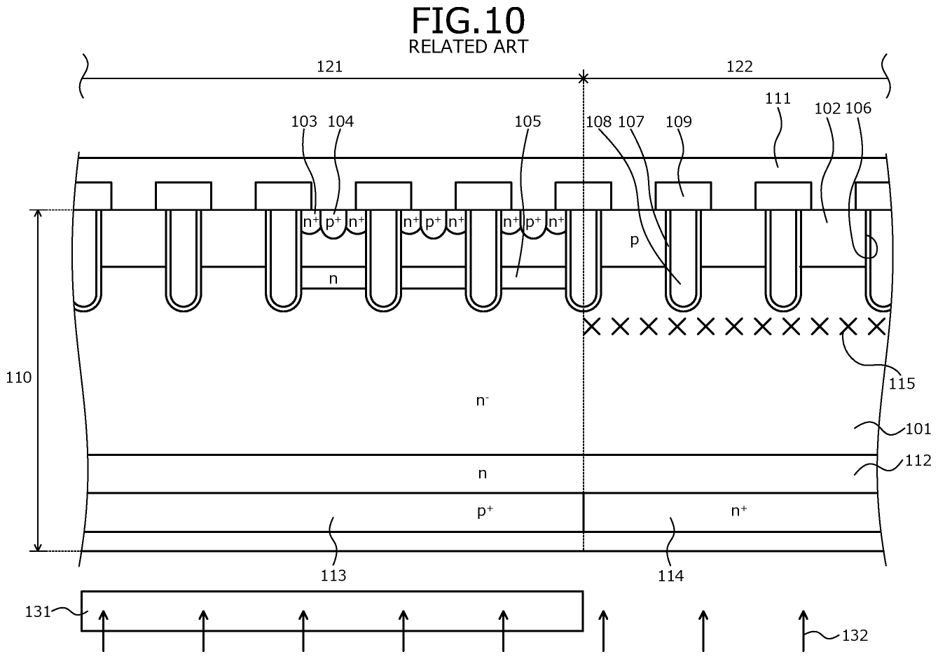

FIG. 11 is a top view of alignment marks in a method of manufacturing the conventional RC-IGBT.

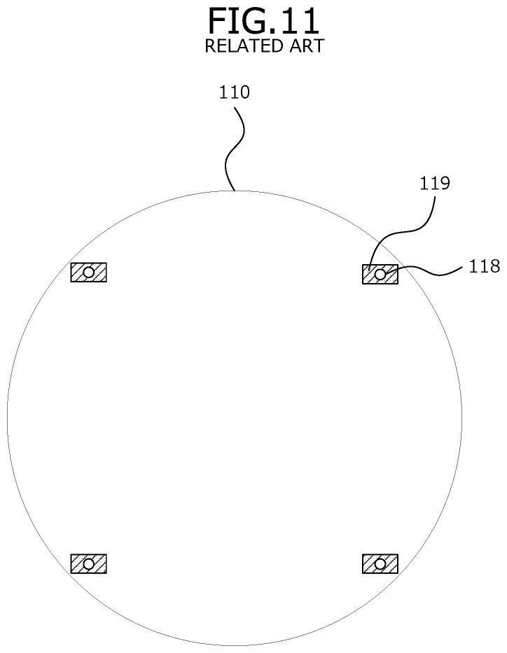

FIG. 12 is a cross-sectional view schematically depicting an annealing furnace in the method of manufacturing the conventional RC-IGBT.

### DETAILED DESCRIPTION OF THE INVENTION

First, problems associated with the conventional techniques above will be discussed. Conventionally, to prevent damage of a front surface (non-irradiated surface) where a semiconductor element is formed, a protective film is formed for protection. For example, a resist film/tape, etc. is used as the protective film. However, at the back surface of the semiconductor wafer 110, no protective film is provided.

Here, a process of equipping a hard mask 131 at the back surface of the semiconductor wafer 110 may be implemented in an environment not at a level of a semiconductor cleanroom, for example, even in a cleanroom, the environment may be of a lower grade (having large amount particulates). In this case, foreign matter may be attached between the hard mask 131 and the back surface of the semiconductor wafer 110. Even when foreign matter is present, after the hard mask 131 is removed after the helium irradiation, both surfaces are cleaned by single wafer processing of the semiconductor wafer 110 and in many cases, the foreign matter may be removed by cleaning both sides in a batch-type cleaning tank thereafter.

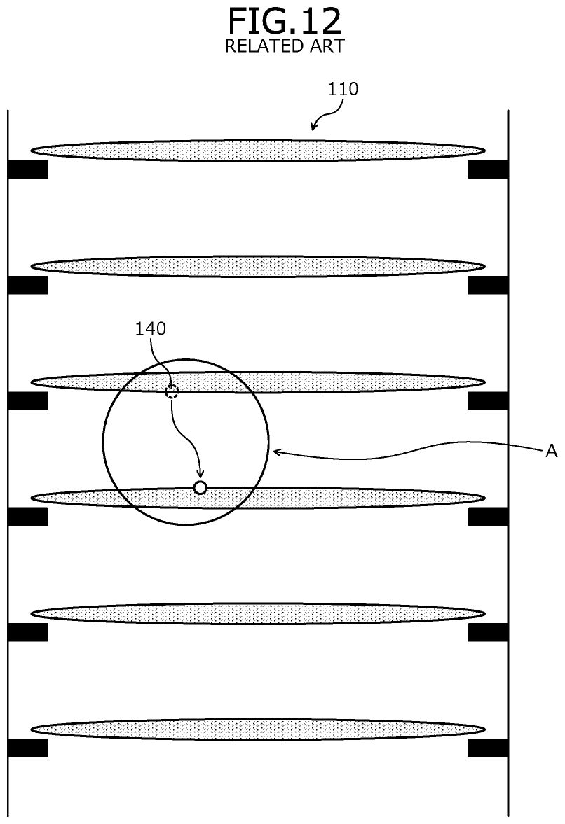

Nonetheless, in some cases foreign matter attached to the semiconductor wafer 110 is not removed by the cleaning processes. For example, foreign matter that easily attaches to silicon, which is a material of the semiconductor wafer 110, is difficult to remove. In this case, foreign matter that is not removed by the cleaning process causes such problems as the following, at a subsequent annealing process (implemented in a vertical furnace). FIG. 12 is a cross-sectional view schematically depicting an annealing furnace in the method of manufacturing the conventional RC-IGBT. When foreign matter that has not be removed by the cleaning process is present and baked, the foreign matter causes defects and as indicated by “A” in FIG. 12, a problem arises in that foreign matter 140 falls on the semiconductor wafer 110 directly below and a defect occurs on the surface of the semiconductor wafer 110 directly below. A further problem arises in that the annealing furnace is contaminated with the foreign matter 140, whereby other semiconductor wafers 110 are contaminated.

Even with the conventional technique of disposing an absorber between the metal mask and the semiconductor wafer, when the process of equipping the absorber and the metal mask to the semiconductor wafer is implemented in an environment not at the level of a semiconductor cleanroom, the absorber is a source of contamination and foreign matter may become attached between the absorber and the back surface of the semiconductor wafer. Therefore, when foreign matter that is not removed by the cleaning processes is present, problems similar to those in a case in which no absorber is present occur.

Embodiments of a method of manufacturing a semiconductor device according to the present invention will be described in detail with reference to the accompanying drawings. In the present description and accompanying drawings, layers and regions prefixed with n or p mean that majority carriers are electrons or holes. Additionally, +or − appended to n or p means that the impurity concentration is higher or lower, respectively, than layers and regions without +or −. In the description of the embodiments below and the accompanying drawings, main portions that are identical will be given the same reference numerals and will not be repeatedly described. Further, in the present description, when Miller indices are described, “−” means a bar added to an index immediately after the “−”, and a negative index is expressed by prefixing “−” to the index.

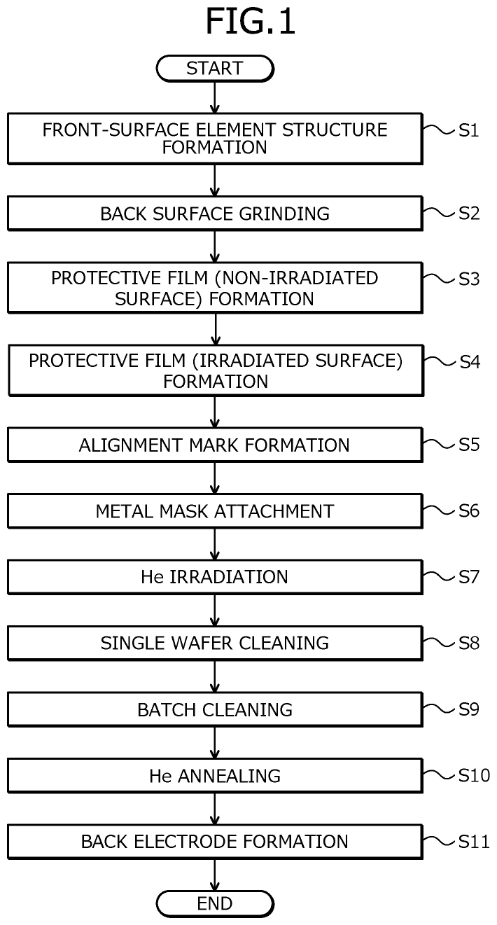

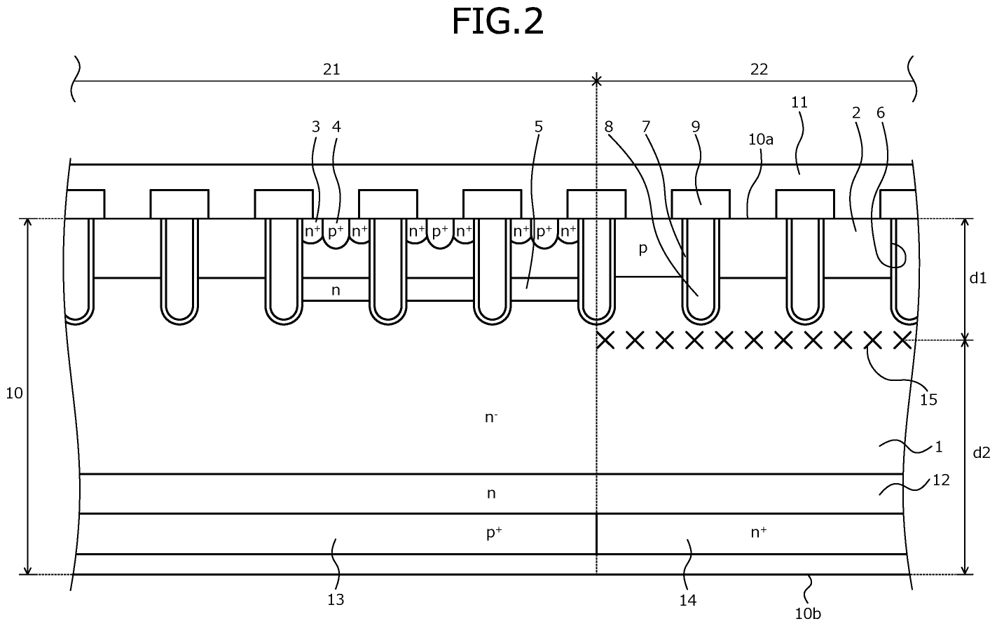

A method of manufacturing a semiconductor device according to an embodiment will be described taking as an example, a RC-IGBT that has a breakdown voltage of 1200V and a FWD region in which helium defects are introduced by helium (He) irradiation. The breakdown voltage is a voltage limit at which no destruction or errant operation of an element occurs. FIG. 1 is a flowchart of an outline of processes of a portion of the method of manufacturing the semiconductor device according to the embodiment. FIGS. 2, 3, and 4 are cross-sectional views schematically depicting states of the semiconductor device in the processes of a portion of the method of manufacturing the semiconductor device according to the embodiment.

The RC-IGBT, for example, includes an IGBT having a trench gate structure and a FWD connected in antiparallel to the IGBT, integrated on a single semiconductor substrate (semiconductor chip). In particular, in an active region on the single semiconductor substrate, an IGBT region 21 that is an operating region of the IGBT and a FWD region 22 that is an operating region of the FWD are provided in parallel (refer to FIG. 2). The active region is a region through which current passes during an ON state. In an edge termination region (not depicted) that surrounds a periphery of the active region, a voltage withstanding structure such as a guard ring or a field plate, etc. may be provided.

First, an element structure is formed at a front surface of the semiconductor device (step S1: first process). As depicted in FIG. 2, a semiconductor wafer (semiconductor substrate of a first conductivity type) 10 that is of an n⁻-type and forms an n⁻-type drift region 1 is prepared. A material of the semiconductor wafer 10 may be silicon (Si) or may be silicon carbide (SiC). Hereinafter, a case in which the semiconductor wafer 10 is a silicon wafer will be described as an example. The semiconductor wafer 10 may have an impurity concentration such that, for example, resistivity is in a range from about 200 Ωm to 900 Ωm. A front surface 10a of the semiconductor wafer 10, for example, may be a (001) plane. The semiconductor wafer 10 may have a thickness (thickness before back grinding described hereinafter) of, for example, 725 μm.

From here, a front-surface element structure is formed. First, a process including photolithography and ion implantation as one set is repeatedly performed under different conditions, whereby at the front surface 10a of the semiconductor wafer 10, the p-type base region 2, n⁺-type emitter regions 3, and p⁺-type contact regions 4 of the IGBT are formed. The p-type base region 2 is formed spanning an entire surface of the active region including the IGBT region 21 and the FWD region 22. The p-type base region 2 serves as a p-type anode region in the FWD region 22. In the IGBT region 21, the n⁺-type emitter regions 3 and the p⁺-type contact regions 4 are selectively formed in the p-type base region 2.

A portion of the semiconductor wafer 10 other than the p-type base region 2, a n-type field stop (FS) layer 12, a p⁺-type collector region 13, and an n⁺-type cathode region 14 described hereinafter forms the n⁻-type drift region 1. In the IGBT region 21, an n-type accumulation layer 5 may be formed between the n⁻-type drift region 1 and the p-type base region 2. The n-type accumulation layer 5 is a barrier of minority carriers (holes) of the n⁻-type drift region 1 when the IGBT turns ON and has a function of accumulating minority carriers in the n⁻-type drift region 1.

Next, the front surface 10a of the semiconductor wafer 10 is thermally oxidized, and a field oxide film covering the front surface 10a of the semiconductor wafer 10 is formed in the edge termination region. Next, in the IGBT region 21, trenches 6 that penetrate the n⁺-type emitter regions 3, the p-type base region 2, and the n-type accumulation layer 5, and reach the n⁻-type drift region 1 are formed by photolithography and etching. The trenches 6, when viewed from the front surface 10a of the semiconductor wafer 10, for example, are disposed in a layout having a striped pattern and extend in a direction (viewing direction in FIG. 2) orthogonal to a direction (horizontal direction in FIG. 2) along which the IGBT region 21 and the FWD region 22 are arranged.

The trenches 6 are further formed in the FWD region 22 in a layout similar to that in the IGBT region 21. In the FWD region 22, the trenches 6 penetrate the p-type base region 2 (p-type anode region) and reach the n⁻-type drift region 1. Next, a gate insulating film 7 is formed along inner walls of the trenches 6, for example, using an oxide film. Next, on the front surface 10a of the semiconductor wafer 10, a polysilicon (poly-Si) layer is formed so as to be embedded in the trenches 6. Next, the polysilicon layer, for example, is etched, leaving portions that form gate electrodes 8 in the trenches 6, respectively.

MOS gates having a trench gate structure are configured by the p-type base region 2, the n⁺-type emitter regions 3, the p⁺-type contact regions 4, the trenches 6, the gate insulating film 7, and the gate electrodes 8. After formation of the gate electrodes 8, the n⁺-type emitter regions 3, the p⁺-type contact regions 4, and the n-type accumulation layer 5 may be formed. The n⁺-type emitter regions 3 suffice to be disposed in at least one mesa region between the trenches 6 that are adjacent to one another and mesa regions in which none of the n⁺-type emitter regions 3 is disposed may be present. Further, the n⁺-type emitter regions 3 may be selectively disposed at predetermined intervals along the direction in which the trenches 6 extend in the striped pattern.

Next, an interlayer insulating film 9 is formed on the front surface 10a of the semiconductor wafer 10, so as to cover the gate electrodes 8. Next, the interlayer insulating film 9 is patterned, thereby forming plural contact holes that penetrate the interlayer insulating film 9 in a depth direction. The depth direction is a direction from the front surface 10a toward a back surface 10bof the semiconductor wafer 10. In the IGBT region 21, the n⁺-type emitter regions 3 and the p⁺-type contact regions 4 are exposed in the contact holes. In the FWD region 22, the p-type base region 2 is exposed in the contact holes.

Next, a front electrode 11 is formed on the interlayer insulating film 9, so as to be embedded in the contact holes. In the IGBT region 21, the front electrode 11 is electrically connected to the p-type base region 2, the n⁺-type emitter regions 3, and the p⁺-type contact regions 4 and functions as an emitter electrode. Further, in the FWD region 22, the front electrode 11 is electrically connected to the p-type base region 2 and functions as an anode electrode. The front electrode 11 may be electrically connected to the p-type base region 2 in mesa regions in which none of the n⁺-type emitter regions 3 is disposed. Next, a passivation film (not depicted) such as that of a polyimide is formed in the edge termination region, whereby the front-surface element structure is completed.

Next, the semiconductor wafer 10 is ground (back grinding) from the back surface 10b(step S2), to a position of a product thickness (for example, about 115 μm) for use as a semiconductor device. In the case of a breakdown voltage of 1200V, the product thickness for use as a semiconductor device, for example, is in a range from about 110 μm to 150 μm. Next, a process including photolithography and ion implantation as one set is repeatedly performed under different conditions, whereby the n-type field stop (FS) layer 12 and the n⁺-type cathode region 14 are formed toward the back surface 10bof the semiconductor wafer 10.

The n⁺-type cathode region 14 is formed at the back surface 10bof the semiconductor wafer 10, in an entire area of a surface layer of the back surface 10bafter the grinding of the semiconductor wafer 10. The n-type field stop layer 12 is formed at a position further from the back surface 10bafter the grinding of the semiconductor wafer 10 than is the n⁺-type cathode region 14. The n-type field stop layer 12 is formed spanning at least the FWD region 22, from the IGBT region 21. The n-type field stop layer 12 may be in contact with the n⁺-type cathode region 14.

Next, by photolithography and ion implantation, a portion of the n⁺-type cathode region 14 corresponding to the IGBT region 21 is changed to a p⁺-type, whereby the p⁺-type collector region 13 is formed. In other words, the p⁺-type collector region 13 is in contact with the n⁺-type cathode region 14 in the direction along which the IGBT region 21 and the FWD region 22 are arranged. The p⁺-type collector region 13 may be in contact with the n-type field stop layer 12 in the depth direction. The state up to here is depicted in FIG. 2.

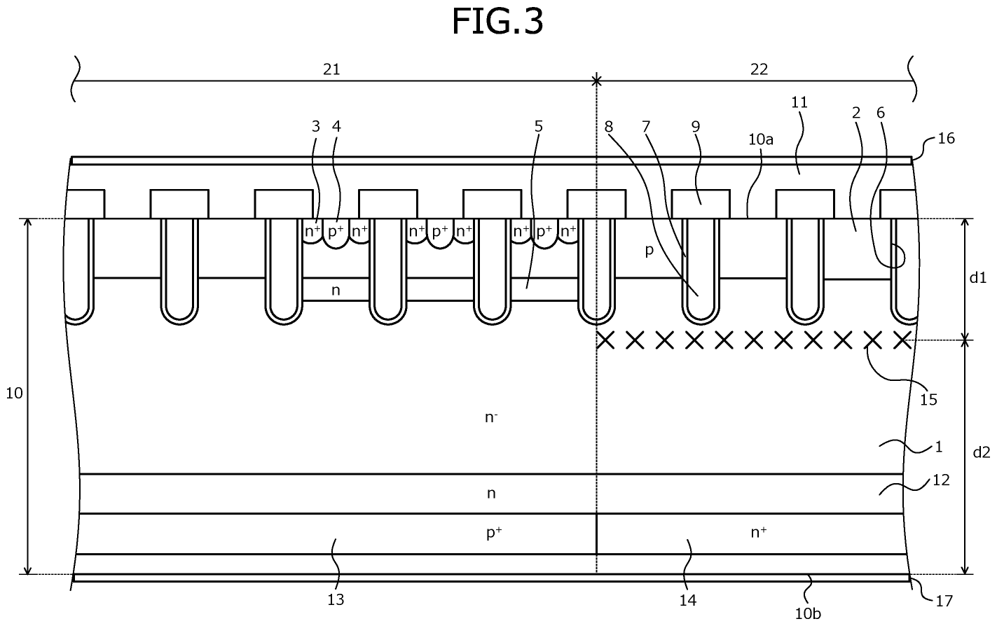

Next, a protective film is formed at a side of the semiconductor wafer 10 having the front surface 10a (non-irradiated surface) (step S3: fifth process). For example, as depicted in FIG. 3, on the front surface 10a of the semiconductor wafer 10, a protective film (second protective film) 16 is formed. For example, the protective film 16 is formed to have a thickness in a range from 1 μm to 10 μm. When the thickness is less than 1 μm, unevenness occurs at a surface of the protective film 16, whereby function as a protective film decreases; and when the thickness is 10 μm or greater, the protective film 16 is difficult to remove and therefore, man-hours for the cleaning process described hereinafter increase.

Next, a protective film is formed at a side of the semiconductor wafer 10 (irradiated surface) having the back surface 10b(step S4: second process). For example, as depicted in FIG. 3, on the back surface 10bof the semiconductor wafer 10, a protective film (first protective film) 17 is formed. For example, the protective film 17 is formed to have a thickness in a range from 1 pm to 8pm. When the thickness is less than 1 pm, unevenness occurs at a surface of the protective film 17, whereby function as a protective film decreases; and when the thickness is 8pm or greater, shielding of He increases due to the protective film 17, whereby variation of the range of He increases.

An irradiation of He described hereinafter is performed via the protective film 17 and therefore, a material of the protective film 17 is a material that He penetrates. For example, a resin material such as a polyimide film, a resist film, a spin on glass (SOG) film, a silicon dioxide (SiO₂) film, a silicon nitride (SiN) film, etc. may be used. The protective film 17 is formed after formation of the front electrode 11 and therefore, may be a film that does not need a high temperature for formation.

Further, the protective film 16 and the protective film 17 may be formed by a similar material. A similar material is a same material or a material of a same type. For example, the protective films 16, 17 may each be formed by a resist and either a positive-type photoresist or a negative-type photoresist may be used for both. Thus, the protective films 16, 17 may be removed concurrently.

Further, the protective film 17 may be formed before the protective film 16. When formed by a material of a same type, the protective films 16, 17 may be formed concurrently.

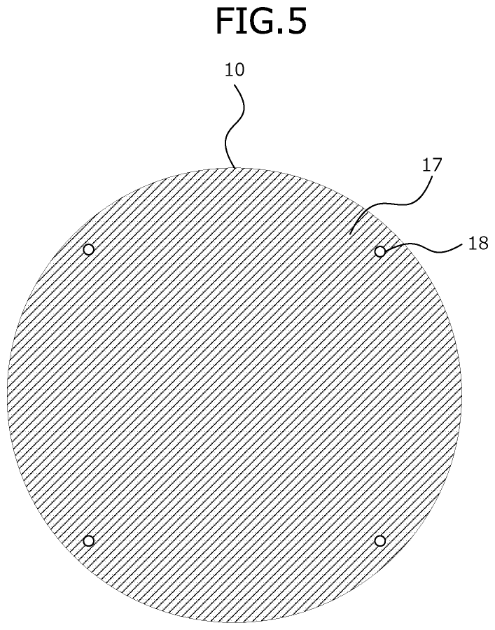

Next, alignment marks are formed (step S5: second process). FIG. 5 is a plan view of alignment marks in the method of manufacturing the semiconductor device according to the embodiment. FIG. 5 is a plan view when the semiconductor wafer 10 is viewed from the back surface 10b. As depicted in FIG. 5, when alignment marks 18 necessary for alignment with a metal mask 31 are formed, a portion of the protective film 17 other than the alignment marks 18 is left and used as a protective film. A shape of the alignment marks 18 in FIG. 5 is an example and the alignment marks 18 may be of any shape like cross-shape, a circle, a rectangle, etc. such that contrast is clear. In the present example, while the alignment marks 18 are formed in the protective film 17, the alignment marks 18 may be formed in the protective film 16, or may be formed in a layer of the front surface 10a other than the front electrode 11, the passivation film (not depicted).

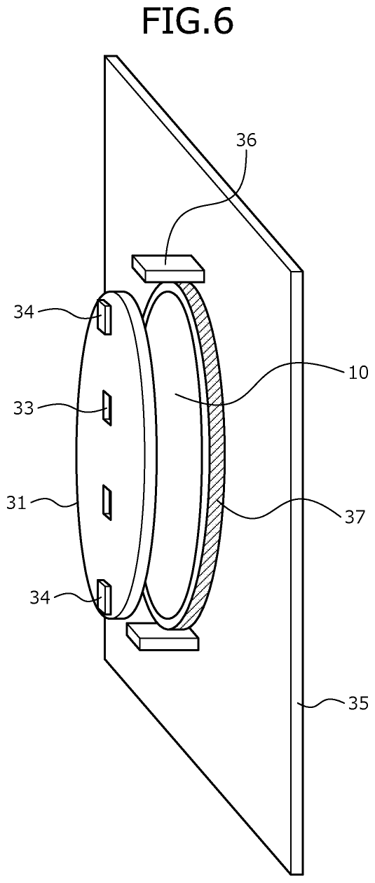

Next, the metal mask is equipped to the semiconductor wafer (step S6). FIG. 6 is a perspective view depicting installation of the metal mask in the method of manufacturing the semiconductor device according to the embodiment. As depicted in FIG. 6, the semiconductor wafer 10 is attached to a plate 35, and the metal mask 31 is disposed facing and aligned with the semiconductor wafer 10.

The plate 35 is a wafer holder that holds the semiconductor wafer 10 when the He irradiation is performed. For example, the plate 35, as depicted in FIG. 6, is equipped with a holding portion 37 that has a substantially annular shape and holds the semiconductor wafer 10 that has a substantially circular shape; and the semiconductor wafer 10 is disposed so that one surface of the semiconductor wafer 10 is exposed from an opening provided in the holding portion 37. Further, the plate 35 is provided with holding members 36; and the metal mask 31, etc. is held by the holding members 36.

In the metal mask 31, openings 33 are provided at portions corresponding to the FWD region 22 and alignment holes 34 are provided. For example, the alignment marks 18 formed in the semiconductor wafer 10 are confirmed through the alignment holes 34, whereby the metal mask 31 is aligned with the semiconductor wafer 10.

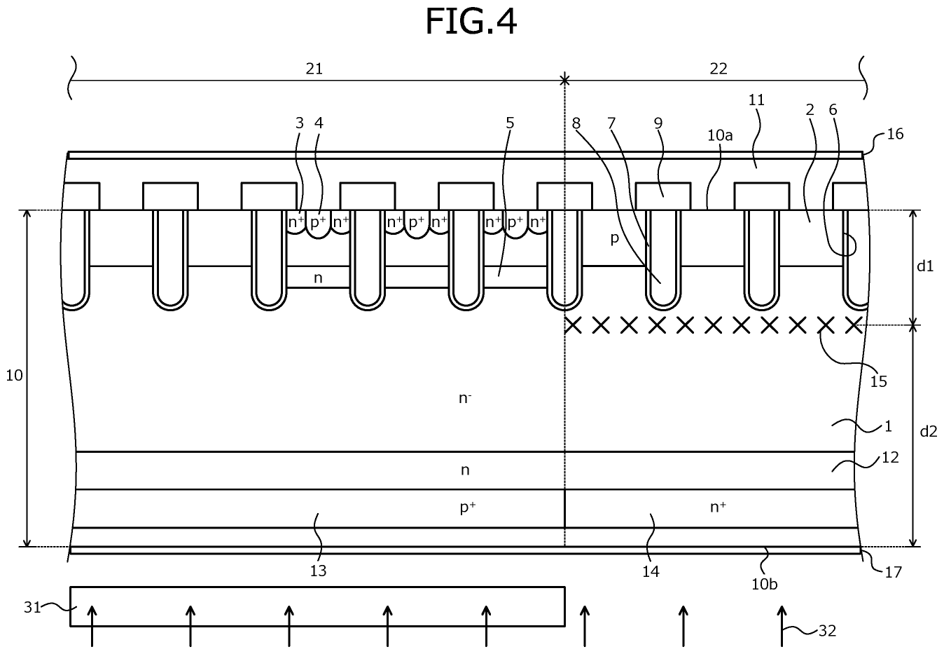

Next, the He irradiation is performed from the back surface of the semiconductor wafer (step S7: third process). As depicted in FIG. 4, an irradiation 32 of helium of a deep range (for example, at least 100 μm) is performed using the metal mask 31 as a mask (shielding film), by a high acceleration energy (for example, 15 MeV or less) from the back surface 10bof the semiconductor wafer 10, whereby helium defects 15 that are lifetime killers are introduced (formed) in the n⁻-type drift region 1. The helium defects 15 are introduced near a border between the n⁻-type drift region 1 and the p-type base region 2 (p-type anode region). An implantation depth (range) d2 of the helium is, for example, about 100 μm from the back surface 10bof the semiconductor wafer 10 and a depth d1 from the front surface 10a is, for example, about 15 μm. The state up to here is depicted in FIG. 4.

Next, the semiconductor wafer 10 and other semiconductor wafers 10 are each cleaned by single wafer processing (step S8) and thereafter, the semiconductor wafer 10 and the other semiconductor wafers 10 are collectively cleaned by batch cleaning (step S9: fourth process). The protective films 16, 17 are removed by the batch cleaning. Here, foreign matter attached to the back surfaces 10bof the semiconductor wafers is removed by liftoff effects during removal and therefore, foreign matter may be suppressed from being attached to the back surfaces 10bof the semiconductor wafers. Therefore, in a He annealing process below, foreign matter is prevented from falling on the semiconductor wafer 10 directly below, thereby enabling contamination of the annealing furnace by foreign matter to be prevented.

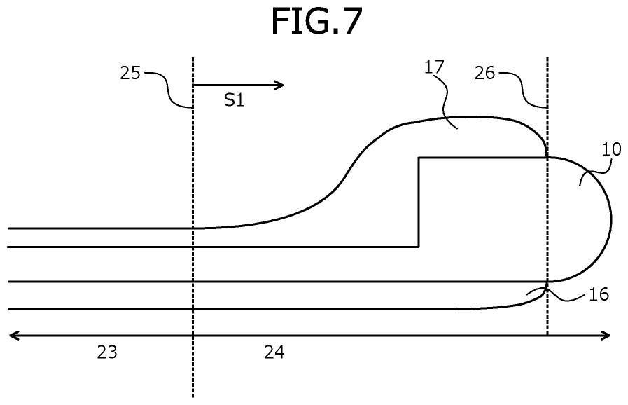

FIG. 7 is a cross-sectional view of an end portion of the semiconductor wafer in the method of manufacturing the semiconductor device according to the embodiment. In FIG. 7, the element structure is not depicted. The protective film 17 formed at the back surface of the semiconductor wafer 10, at a wafer end portion 24, particularly, a part in contact with the holding portion 37 of the wafer holder may be removed. A portion (in a region S1 in FIG. 7) closer to an end of the semiconductor wafer 10 than is a device-region outer peripheral end 25 suffices to be removed. When the protective film 17 is a resist film, the resist film may be removed by a chemical agent and therefore, throughput is increased. However, to make it difficult for foreign matter to enter the semiconductor wafer 10, a portion formed in the wafer end portion 24 may be left while a portion closer to the end of the semiconductor wafer 10 than is a release surface 26 of the wafer end portion 24 may be removed. The portion closer to the end of the semiconductor wafer 10 than is the release surface 26 is a rounded portion and a side wall of the semiconductor wafer 10. When the protective film 17 is a resist film, removal may be by exposing the wafer end portion 24 by a peripheral exposure device or an edge release function of a spin-coater. Controllability is higher with the peripheral exposure device. Similarly, the protective film 16 formed at the front surface of the semiconductor wafer 10, a portion closer to the end of the semiconductor wafer 10 than is a device region 23, particularly, a portion in contact with the holding portion 37 of the wafer holder may be removed.

Next, the He annealing is performed (step S10). Helium lattice defects formed in the n⁻-type drift region 1 by the He irradiation are recovered, thereby adjusting an amount of lattice defects in the semiconductor wafer 10. As a result, carrier lifetime may be adjusted.

Next, a back electrode (not depicted) is formed at the back surface 10b of the semiconductor wafer 10 overall (step S11). The back electrode is in contact with the p⁺-type collector region 13 and the n⁺-type cathode region 14. The back electrode functions as a collector electrode and functions as a cathode electrode. Thereafter, the semiconductor wafer 10 is cut (diced) into individual chips, whereby a RC-IGBT chip (semiconductor chip) is completed.

While a case in which the He irradiation is performed only to the FWD region 22 has been described, the He irradiation may be performed to the entire surface without providing the metal mask 31. In this case, while the metal mask 31 is not used, for the He irradiation, the semiconductor wafer 10 may be carried in an environment not at the level of a semiconductor cleanroom level and foreign matter may be attached to the back surface 10b. Therefore, the protective film is provided at the back surface 10b, whereby foreign matter may be suppressed from being attached to the semiconductor wafer 10. Further, when the semiconductor wafer 10 is attached to the plate 35, foreign matter from the plate 35 may become attached to the semiconductor wafer 10. This foreign matter may also be removed when the protective films 16, 17 are removed.

As described above, according to the embodiment, the protective film is formed at the front surface (non-irradiated surface) of the semiconductor wafer. As a result, foreign matter attached to the back surface of the semiconductor wafer is removed by the liftoff effects during removal when the protective film is removed and foreign matter may be suppressed from being attached to the semiconductor wafer. Therefore, in the annealing process, foreign matter may be prevented from falling on a semiconductor wafer directly below and contamination of the annealing furnace by foreign matter may be prevented.

In the present invention, without limitation to the embodiment described above, various modifications within a range not departing from the spirit of the invention are possible. For example, in the embodiment described above, while a case in which helium is irradiated, without limitation hereto, the present invention is applicable when ion implantation of a predetermined impurity is performed. Further, in the embodiment described above, while a RC-IGBT is described as an example, without limitation hereto, the present invention is applicable to a device that has various element structures for which ion implantation of an impurity and helium irradiation by a high acceleration energy are performed under the conditions described above. For example, application is possible to a semiconductor device having a combination of a FWD introduced with lifetime killers and another semiconductor element. Further, dimensions, impurity concentrations, etc. of regions may be variously set according to required specifications. The present invention is similarly implemented when the conductivity types (n-type, p-type) are reversed.

According to the invention described above, the protective film (first protective film) is formed at the back surface (irradiated surface) of the semiconductor wafer (semiconductor substrate of the first conductivity type). As a result, foreign matter attached to the back surface of the semiconductor wafer is removed by the liftoff effects during removal when the protective film is removed and foreign matter may be suppressed from being attached to the semiconductor wafer. Therefore, in the annealing process, foreign matter may be prevented from being baked and causing defects, and may be prevented from falling on a semiconductor wafer directly below. Further, contamination of the annealing furnace by foreign matter may be prevented.

The method of manufacturing a semiconductor device according to the present invention achieves an effect in that foreign matter may be suppressed from being attached to the semiconductor wafer when high-acceleration ion implantation of a deep range is implemented.

As described, the method of manufacturing a semiconductor device according to the invention is useful for semiconductor devices requiring high-acceleration ion implantation to be performed.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A method of manufacturing a semiconductor device that includes a semiconductor element, the method comprising:
providing a semiconductor substrate of a first conductivity type;
forming an element structure of the semiconductor element, at a first main surface of the semiconductor substrate;
forming a first protective film at a second main surface of the semiconductor substrate;
implanting ions in the semiconductor substrate from the second main surface having the first protective film formed thereon; and
removing the first protective film.

2. The method according to claim 1, further comprising
forming a second protective film at the first main surface of the semiconductor substrate after forming the element structure but before implanting the ions in the semiconductor substrate.

3. The method according to claim 2, wherein
the first protective film and the second protective film are formed using a same material.

4. The method according to claim 2, wherein
the first protective film is so formed that an end portion of the semiconductor substrate is exposed from the first protective film.

5. The method according to claim 2, wherein
forming the second protective film includes forming an alignment mark in the second protective film.

6. The method according to claim 1, wherein
forming the first protective film includes forming an alignment mark in the first protective film.

7. The method according to claim 1, wherein
forming the element structure includes forming an alignment mark at the first main surface of the semiconductor substrate.

8. The method according to claim 1, further comprising
grinding the second main surface of the semiconductor substrate between forming the element structure and forming the first protective film.

9. The method according to claim 1, further comprising
providing a metal mask at the second main surface of the semiconductor substrate after forming the first protective film but before implanting ions in the semiconductor substrate.

10. The method according to claim 1, further comprising
forming a back-surface structure of the semiconductor element, at the second main surface of the semiconductor substrate after forming the element structure but before forming the first protective film.
